(19) United States
(12) Patent Application Publication
(10) Pub. No.: US 2024/0183033 A1
(43) Pub. Date: Jun. 6, 2024

(54) MULTI-PULSE DEPOSITION PROCESSES

(71) Applicant: Applied Materials, Inc., Santa Clara, CA (US)

(72) Inventors: Tianyi Huang, Santa Clara, CA (US); Srinivas Gandikota, Santa Clara, CA (US); Yixiong Yang, Fremont, CA (US); Elizabeth Mao, Sunnyvale, CA (US); Chi-Chou Lin, San Jose, CA (US)

(73) Assignee: Applied Materials, Inc., Santa Clara, CA (US)

(21) Appl. No.: 18/074,197

(22) Filed: Dec. 2, 2022

(51) Int. Cl. C23C 16/455; C23C 16/34; H01L 21/3205; H01L 21/768

(52) U.S. Cl. CPC C23C 16/45527; C23C 16/34; H01L 21/32051; H01L 21/76843

(57) ABSTRACT

Embodiments of the present disclosure advantageously provide improved control over precursor/reactant pulse/purge time, greater growth per cycle, and higher throughput during formation of a metal-containing film on a substrate surface (including substrate surfaces having at least one feature) compared to traditional atomic layer deposition (ALD) processes. In some embodiments, forming the metal-containing film comprises exposing a substrate to a constant flow of an inert carrier gas and a co-flow of a pulse of a metal-containing precursor and a pulse of a reactant. The pulse of the metal-containing precursor and the pulse of the reactant may be interrupted by a mini purge. The metal-containing precursor and/or the reactant may be charged during the mini purge to avoid precursor/reactant depletion.

### TECHNICAL FIELD

Embodiments of the present disclosure pertain to the field of electronic device manufacturing, and in particular, to integrated circuit (IC) manufacturing. In particular, embodiments of the disclosure are directed to multi-pulse deposition processes for forming conformal films at a high growth rate.

### BACKGROUND

As circuit integration increases, there is an enhanced need for greater uniformity and process control regarding layer thickness. As a result, various technologies have been developed to deposit layers on substrates in a cost-effective manner, while maintaining control over the characteristics of the layer. Chemical vapor deposition (CVD) is one of the most common deposition processes employed for depositing layers on a substrate. CVD includes processes for depositing thin films by exposing the substrate to one or more volatile precursors, which react and/or decompose on the substrate surface.

A variant of CVD that demonstrates excellent step coverage is cyclical deposition or atomic layer deposition (ALD). ALD employs chemisorption techniques to deliver precursor molecules on a substrate surface in sequential cycles. An ALD cycle includes exposing the substrate surface to a first precursor, a purge gas, a second precursor, and the purge gas. The first and second precursors react to form a product compound as a film on the substrate surface. The ALD cycle is repeated to form the film to a desired thickness.

The advancing complexity of advanced microelectronic devices is placing stringent demands on currently used deposition techniques. Lower growth rates lead to conformal growth whereas higher growth rates (e.g., above about 1 Å/cycle) tend to grow non-conformal films. Growth rates (also referred to as deposition rates) are expressed as an average thickness deposited per cycle. Conventional CVD lacks the capability to grow highly conformal thin films, especially on 3D microstructures for modern front-end/mid-end semiconductor processes. Conformal deposition is often required in order to uniformly deposit a metal film over three-dimensional structures including high aspect ratio features. ALD processes produce conformal films, and consequently have lower growth rates than conventional CVD processes.

Accordingly, there is a need for improved processes for forming conformal films at a higher growth rate.

### SUMMARY

One or more embodiments are directed to a processing method comprising exposing a substrate to a constant flow of an inert gas and a co-flow of a pulse of a metal-containing precursor and a pulse of a reactant to form a metal-containing film on the substrate, the pulse of the metal-containing precursor and the pulse of the reactant interrupted by a mini purge, wherein the metal-containing precursor is charged during the mini purge.

Additional embodiments are directed to a processing method comprising exposing a substrate including at least one feature to a process cycle. The at least one feature comprises a surface defining a trench. The trench has a top surface, a bottom surface, and two opposed sidewalls comprising a dielectric material. The process cycle comprises exposing the top surface, the bottom surface, and the two opposed sidewalls to a constant flow of an inert gas and a co-flow of a pulse of a metal-containing precursor and a pulse of a reactant to conformally deposit a metal-containing film on the at least one feature, the pulse of the metal-containing precursor and the pulse of the reactant interrupted by a mini purge, wherein the metal-containing precursor is charged during the mini purge.

Further embodiments are directed to a processing tool comprising a central transfer station comprising a robot configured to move a wafer; a plurality of process stations, each process station connected to the central transfer station and providing a processing region separated from processing regions of adjacent process stations. The plurality of process stations comprises one or more of a chemical vapor deposition (CVD) chamber or an atomic layer deposition (ALD) chamber. The processing tool comprises a controller connected to the central transfer station and the plurality of process stations. The controller is configured to activate the robot to move the wafer between process stations, and to control a processing method for forming a metal-containing film on the wafer, the processing method comprising exposing the wafer to a constant flow of an inert gas and a co-flow of a pulse of a metal-containing precursor and a pulse of a reactant to form the metal-containing film, the pulse of the metal-containing precursor and the pulse of the reactant interrupted by a mini purge, wherein the metal-containing precursor is charged during the mini purge.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a flow diagram of a processing method according to one or more embodiments;

FIG. 2 illustrates a schematic cross-sectional view of a substrate according to one or more embodiments;

FIG. 3A illustrates a schematic cross-sectional view of a substrate including a feature according to one or more embodiments;

FIG. 3B illustrates a schematic cross-sectional view of a substrate including a feature according to one or more embodiments;

FIG. 3C illustrates a schematic cross-sectional view of a substrate including a feature according to one or more embodiments; and

FIG. 4 illustrates a schematic top-view diagram of a multi-chamber processing system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used herein, the term “substrate surface” refers to any substrate surface upon which a layer may be formed. The substrate surface may have one or more features formed therein, or thereon, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top surface, two opposed sidewalls and a bottom surface, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which can be the same as or different from the sidewall material.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

As used herein, the term “liner” refers to a layer formed (e.g., conformally formed) along at least a portion of the sidewalls and/or bottom surface of an opening (e.g., a trench) such that a substantial portion of the trench prior to the deposition of the layer remains unfilled after deposition of the layer. In some embodiments, the liner may be formed along the entirety of the sidewalls and bottom surface of the trench. A liner may also be formed on a flat surface of a flat substrate.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In one or more embodiments, a liner and/or a film is conformally deposited on a surface. As used herein, the term “conformal”, or “conformally”, refers to a film that adheres to and uniformly covers exposed surfaces with a thickness having a variation of less than 5%, less than 2%, or less than 1% relative to the average thickness of the film. For example, a 1,000 Å thick film may have less than a 10 Å variation in thickness. This thickness and variation includes at least edges, corners, sides, and the bottom of recesses. For example, a conformal film deposited by ALD in various embodiments of the disclosure would provide coverage over the deposited region of essentially uniform thickness on complex surfaces.

As used herein, the term “in situ” refers to processes that are all performed in the same processing chamber or within different processing chambers that are connected as part of a processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowire channels, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

In the manufacture of integrated circuits, contact level metallization schemes are often used to provide low resistance contacts to an underlying semiconductor material. Embodiments of the present disclosure provide methods that are particularly useful in contact level metallization schemes. One or more embodiments are directed to methods of depositing metal films at low temperatures. In some embodiments, the methods advantageously include depositing metal films for contacts and multilevel interconnects, as an example, at a temperature of less than or equal to 500° C. Without intending to be bound by theory, it is thought that low temperature is critical due to low-K dielectric materials in which trenches and vias are patterned. It is also thought that high deposition temperature, such as, for example, temperatures greater than 500° C., may lead to mechanical deformation of low-K dielectric materials, faster & higher diffusion of metal atoms or byproducts into low-K dielectric materials which changes K-value, breakdown voltage and increases resistive capacitance (RC) delay.

Embodiments of the disclosure are directed to methods with improved control over precursor/reactant pulse/purge time. Some embodiments of the disclosure advantageously provide methods with greater growth per cycle. Some embodiments of the disclosure provide methods with higher throughput.

In one or more embodiments, a unique combination of mass flow controller (MFC) and programmable logic controller (PLC) is advantageously used to provide the capability of precise control of chemical delivery (e.g., a precursor and/or a reactant) and purging in chemical vapor deposition (CVD) chambers to a time scale of milliseconds. Delivery flow rate, chemical concentration, purge frequency can be manipulated to allow CVD-like rapid growth of semiconductor or metal thin films with superior conformality similar to atomic layer deposition (ALD). The MFC and the PLC can be positioned in any suitable configuration such that the chemical delivery (e.g., a metal-containing precursor and/or a reactant) may be controlled. In some embodiments, the MFC and the PLC are positioned on the same chemical delivery (e.g., a metal-containing precursor and/or a reactant) line within a processing chamber for forming a metal-containing film. In some embodiments, the MFC is continuously on, such that the metal-containing precursor/reactant is continuously flowing. In some embodiments, the PLC is used to control a valve (e.g., a PLC-controlled valve) that controls whether the metal-containing precursor/reactant is delivered to the processing chamber during the continuous MFC flow of the metal-containing precursor/reactant. As used herein, the term “PLC is on/open” means that the PLC opens the PLC-controlled valve and allows the metal-containing precursor/reactant to be delivered to the processing chamber during the continuous MFC flow of the metal-containing precursor/reactant. As used herein, the term “PLC is off/closed” means that the PLC closes the PLC-controlled valve and does not allow the metal-containing precursor or the reactant to be delivered to the processing chamber during the continuous MFC flow of the metal-containing precursor/reactant. When both of the MFC and the PLC are on (e.g., open), the MFC provides continuous flow of the metal-containing precursor/reactant and the PLC keeps the PLC-controlled valve open, such that the flow of the metal-containing precursor/reactant continues. When both of the MFC and the PLC are off, there is no delivery of the inert gas, the metal-containing precursor, and/or the reactant to the processing chamber, and neither the metal-containing precursor nor the reactant are being charged.

Embodiments of the present disclosure advantageously provide mini purges (i.e., a purge in a range of from greater than or equal to 50 milliseconds to less than or equal to 1000 milliseconds) to interrupt the co-flow of the metal-containing precursor and the reactant by using the PLC to close the PLC-controlled valve of the metal-containing precursor and/or the reactant while the MFC is continuously on. Embodiments of the present disclosure advantageously provide processing methods where, simultaneously with the mini purge, the metal-containing precursor and/or the reactant may be charged by keeping the MFC open and using the PLC to close the PLC-controlled valve, to avoid depletion of metal-containing precursor and/or the reactant. Embodiments of the present disclosure advantageously provide processing methods where, simultaneously with the mini purge, the substrate is cleaned, thus allowing for conformal growth on the clean substrate surface. Embodiments of the present disclosure also allows purging of the processing chamber with both the PLC-controlled valve and MFC closed (e.g., off) for the metal-containing precursor and/or the reactant, after the co-flowing (similar to conventional ALD or pulsed CVD).

In one or more embodiments, provided is conformal deposition for ultrathin film (3-30 Å) deposition. It was surprisingly found that co-flowing the metal-containing precursor the reactant yielded greater than 300% throughput improvement compared to traditional ALD processes, described in further detail in the Examples section below. Such rapid growth rates successfully satisfy throughput improvement demands for new metal gate stack materials.

In some embodiments, the processing chamber is purged to remove unreacted precursor, unreacted reactant, reaction products, and by-products. In specific embodiments, the processing chamber is purged after exposure to the metal-containing precursor and/or the reactant. As used in this manner, the term “processing chamber” also includes portions of a processing chamber adjacent the substrate surface without encompassing the complete interior volume of the processing chamber. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur.

As used herein, the term “mini purge” refers to a purge process to remove unreacted precursor, unreacted reactant, reaction products, and by-products from a processing chamber for a time period in a range of from greater than or equal to 50 milliseconds to less than or equal to 1000 milliseconds, including all subranges and values therebetween, such as in the range of from greater than or equal to 50 milliseconds to 500 milliseconds. During the mini purge, the metal-containing precursor and/or the reactant may be charged by keeping the MFC open and using the PLC to close the PLC-controlled valve, to avoid depletion of metal-containing precursor and/or the reactant. In some embodiments, during the mini purge, the substrate surface can be cleaned, thus allowing for conformal growth on the clean substrate surface.

As used herein, the term “long purge” refers to a purge process to remove unreacted precursor, unreacted reactant, reaction products, and by-products from a processing chamber for a time period in a range of from greater than or equal to 500 milliseconds to less than or equal to 10 seconds, including all subranges and values therebetween, such as in the range of from greater than or equal to 1 second to less than or equal to 10 seconds. In some embodiments, the long purge includes flowing a purge gas over the substrate. During the long purge, in some embodiments, both of the MFC and the PLC are off, there is no delivery of the inert gas, the metal-containing precursor, and/or the reactant to the processing chamber, and neither the metal-containing precursor nor the reactant are being charged. In some embodiments, during the long purge, the metal-containing precursor and/or the reactant may be charged by keeping the MFC open and using the PLC to close the PLC-controlled valve.

Embodiments of the present disclosure advantageously provide methods that are particularly useful in forming metal-containing films for various applications, including, but not limited to metal gate stacks (e.g., high-k metal gate (HKMG) stacks), dipole layers, capping layers, liner layers and the like. Another aspect of the disclosure pertains to a method that is part of a gap fill process.

Further embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

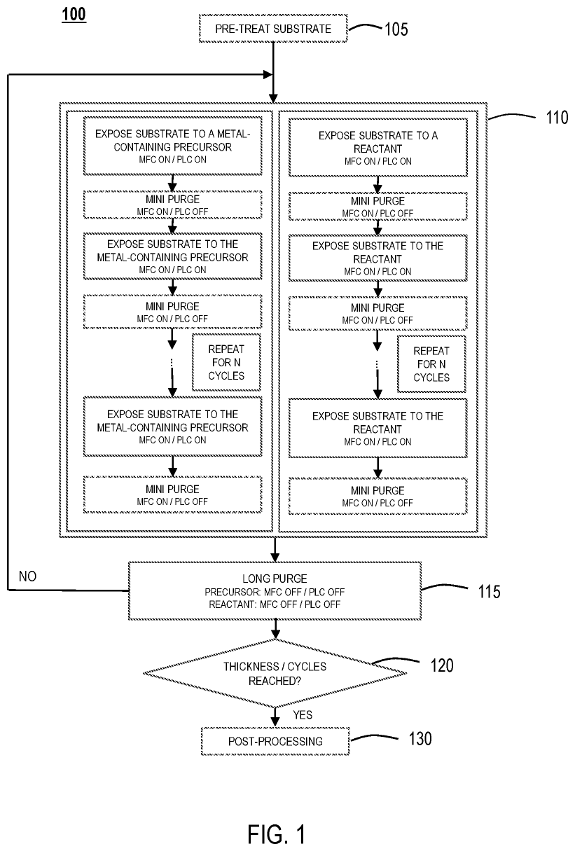

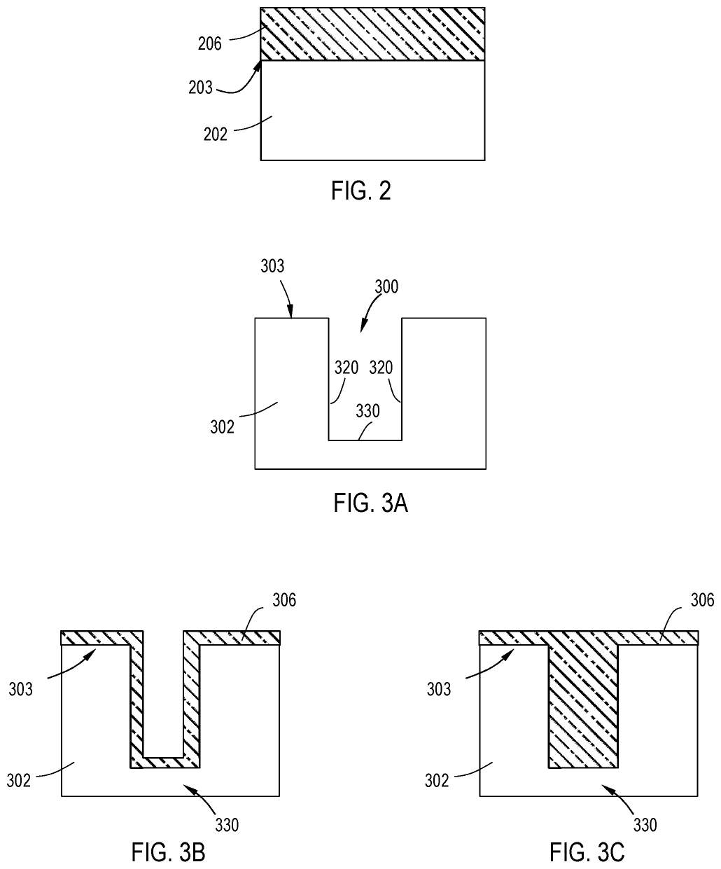

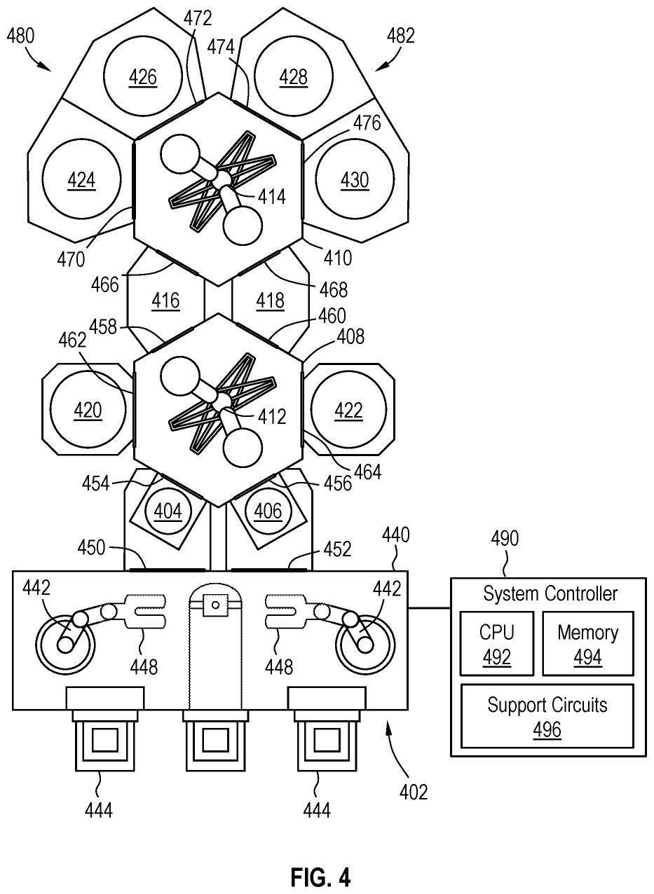

FIG. 1 illustrates a flow diagram of a processing method 100 of forming a metal-containing film on a substrate. FIG. 2 illustrates a schematic cross-sectional view of a substrate. FIGS. 3A-3C illustrate schematic cross-sectional views of a substrate including a feature. FIG. 4 illustrates a schematic top-view diagram of a multi-chamber processing system.

Referring to FIG. 1, in some embodiments, the processing method 100 includes a pre-treatment operation 105. The pre-treatment can be any suitable pre-treatment known to the skilled artisan. Suitable pre-treatments include, but are not limited to, pre-heating, cleaning, soaking, native oxide removal, or deposition of a layer.

At operation 110, the processing method 100 comprises exposing a substrate to a constant flow of an inert gas and a co-flow of a pulse of a metal-containing precursor and a pulse of a reactant to form a metal-containing film on the substrate. In some embodiments, the constant flow of the inert gas is used to carry the metal-containing precursor and/or the reactant to the substrate. In some embodiments, the inert gas comprises one or more of nitrogen (N₂), argon (Ar), or helium (He). In some embodiments, the inert gas comprises argon (Ar).

Advantageously, in some embodiments, the PLC allows the metal-containing precursor and/or the reactant to be charged during the processing method 100. Embodiments of the present disclosure are particularly useful for avoiding precursor depletion, for example, when the metal-containing precursor is a low vapor pressure solid. In some embodiments, the metal-containing precursor and the reactant are charged during the mini purge to avoid precursor/reactant depletion.

At operation 110, the co-flow of the pulse of the metal-containing precursor and the pulse of the reactant is shown. During the co-flow of the pulse of the metal-containing precursor and the pulse of the reactant, the MFC is on (providing a continuous flow of the metal-containing precursor and the reactant) and the PLC is on (so that the co-flow of the pulse of the metal-containing precursor and the pulse of the reactant is delivered to the processing chamber and exposed to the substrate). The pulse of the metal-containing precursor and/or the pulse of the reactant may be interrupted by a mini purge (where the PLC is off). The metal-containing precursor and/or the reactant may be charged during the mini purge.

It was surprisingly found that co-flowing the pulse of the metal-containing precursor and the pulse of the reactant (as in processing method 100) yielded greater than 300% throughput improvement compared to traditional ALD processes, described in further detail in the Examples section below.

The metal-containing precursor may comprise any suitable precursor known to the skilled artisan. In some embodiments, the metal-containing precursor is a low vapor pressure solid. In some embodiments, the metal-containing precursor is a liquid precursor. In some embodiments, the metal-containing precursor comprises a transition metal. In some embodiments, the metal-containing precursor comprises one or more of aluminum chloride (AlCl₃), hafnium tetrachloride (HfCl₄), niobium chloride (NbCl₅), molybdenum pentachloride (MoCl₅), tungsten pentachloride (WCl₅), tungsten hexachloride (WCl₆), tungsten (V) chloride (W₂Cl₁₀), molybdenum dioxide dichloride (MoO₂Cl₂), tungsten oxytetrachloride (WOCl₄), antimony trichloride (SbCl₃), tellurium tetrachloride (TeCl₄), tantalum pentachloride (TaCl₅), Tris(N,N′-di-i-propylformamidinato) lanthanum (III), Tetrakis(dimethylamino) titanium (TDMAT), Pentakis(dimethylamino) tantalum (PDMAT). In some embodiments, the metal-containing precursor comprises aluminum chloride (AlCl₃).

The reactant may be any suitable reactant known to the skilled artisan. In some embodiments, the reactant may be any suitable reactant for a CVD type process and/or ALD type process known to the skilled artisan. In some embodiments, the reactant includes, but is not limited to hydrogen (H₂), water (H₂O), oxygen (O₂), ozone (O₃), nitrogen (N₂), ammonia (NH₃), methanol (MeOH), ethanol (EtOH), ethylene (C₂H₄), and the like.

In some embodiments, the pulse of the metal-containing precursor is longer than the pulse of the reactant. In some embodiments, the pulse of the metal-containing precursor is in a range of from greater than or equal to 50 milliseconds to less than or equal to 500 milliseconds, including all subranges and values therebetween. In some embodiments, the pulse of the reactant is in a range of from greater than or equal to 500 milliseconds to less than or equal to 1 second, including all subranges and values therebetween.

In some embodiments, the pulse of the reactant is longer than the pulse of the metal-containing precursor. In some embodiments, the pulse of the reactant is in a range of from greater than or equal to 50 milliseconds to less than or equal to 500 milliseconds, including all subranges and values therebetween. In some embodiments, the pulse of the metal-containing precursor is in a range of from greater than or equal to 500 milliseconds to less than or equal to 1 second.

In some embodiments, the pulse of the metal-containing precursor is in a range of from greater than or equal to 50 milliseconds to less than or equal to 500 milliseconds, including all subranges and values therebetween. In some embodiments, the pulse of the reactant is in a range of from greater than or equal to 50 milliseconds to less than or equal to 500 milliseconds.

It has been advantageously found that during processing method 100, the mini purge of the processing chamber (and the substrate surface) cleans the substrate surface for conformal growth of a metal-containing film thereon.

In some embodiments, the metal-containing precursor comprises aluminum chloride (AlCl₃) and the reactant comprises ammonia (NH₃) to form a metal-containing film comprising aluminum nitride (AlN). In some embodiments, the metal-containing film has a thickness in a range of from 3 Å to 200 Å, including all subranges and values therebetween.

In some embodiments, the processing method 100 is performed at a temperature in a range of 200° C. to 500° C., including all subranges and values therebetween. In some embodiments, the processing method 100 is performed at a pressure in a range of from 2 Torr to 300 Torr, including all subranges and values therebetween. Without intending to be bound by theory, it is thought that increased pressure, such as pressure in the range of from greater than or equal to 100 Torr to less than or equal to 300 Torr, can be achieved by choking chamber conductance with smaller volume/spacing, choked pumping liner and high sealed throttle valve.

Advantageously, it has been found that the improved control over precursor/reactant pulse/purge time to less than or equal to 0.05 seconds achieved by the PLC optimizes the removal of unreacted precursor, unreacted reactant, reaction products, and by-products. In some embodiments, the metal-containing precursor and/or the reactant are charged during the mini purge to avoid precursor/reactant depletion.

At operation 115, the processing chamber is purged (e.g., a long purge). for a time period in a range of from greater than or equal to 500 milliseconds to less than or equal to 10 seconds, including all subranges and values therebetween, such as such as in the range of from greater than or equal to 1 second to less than or equal to 10 seconds. In some embodiments, at operation 115, both of the MFC and the PLC are off, there is no delivery of the inert gas, the metal-containing precursor, and/or the reactant to the processing chamber, and neither the metal-containing precursor nor the reactant are being charged. In other embodiments, during the long purge (operation 115), the metal-containing precursor and/or the reactant may be charged by keeping the MFC open and using the PLC to close the PLC-controlled valve.

At decision point 120, in one or more embodiments, the thickness of the deposited film, and/or number of times (e.g., n cycles that may be repeated) the processing method 100 has been performed is considered. In one or more embodiments, if the deposited film has reached a predetermined thickness or a predetermined number of process cycles have been performed, the processing method 100 moves to a post-processing operation 130. In one or more embodiments, if the thickness of the deposited film or the number of times the processing method 100 has been performed has not reached a predetermined threshold, the processing method 100 returns to operation 110 to, again, expose the substrate to the constant flow of the inert gas and the co-flow of the pulse of the metal-containing precursor and the pulse of the reactant. In some embodiments, the processing method 100 is repeated in a range of 1 to 10 times (e.g., in a range of from 1 to 10 cycles).

In one or more embodiments, the post-processing operation 130 comprises, for example, a process to modify film properties (e.g., annealing) or a further film deposition process (e.g., additional ALD or CVD processes) to grow additional films. In some embodiments, the post-processing operation 130 includes a process that modifies a property of the deposited film. In some embodiments, the post-processing operation 130 comprises annealing the as-deposited film. In some embodiments, annealing is performed at temperatures in the range of about 300° C., 400° C., 500° C., 600° C., 700° C., 800° C., 900° C. or 1000° C. The annealing environment of some embodiments comprises one or more of an inert carrier gas (e.g., molecular nitrogen (N₂), argon (Ar), or helium (He)) or a reducing gas (e.g., molecular hydrogen (H₂) or ammonia (NH₃)) or an oxidant, such as, but not limited to, oxygen (O₂), ozone (O₃), or peroxides. In one or more embodiments, annealing is performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

FIG. 2 illustrates a schematic cross-sectional view of a substrate 202 having a metal-containing film 206 thereon. In some embodiments, the metal-containing film 206 is the metal-containing film that is formed in processing method 100.

The substrate 202 can be any suitable substrate material. In one or more embodiments, the substrate 202 comprises a semiconductor material, e.g., any metal material, silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), a high-K dielectric material other semiconductor materials, or any combination thereof. In one or more embodiments, the substrate 202 comprises one or more of silicon (Si), germanium (Ge), gallium (Ga), arsenic (As), indium (In), phosphorus (P), or selenium (Se). Although a few examples of materials from which the substrate 202 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the substrate 202 may include dielectric materials, for example, silicon-containing dielectric materials and/or metal oxide dielectric materials. In some embodiments, the substrate 202 may comprise one or more dielectric surfaces comprising a low-K dielectric material such as, but not limited to, silicon oxide (SiOx), silicon sub-oxides, silicon nitride (SiNₓ), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof.

In FIG. 2, the metal-containing film 206 is formed on a top surface 203 of the substrate 202. In some embodiments, the metal-containing film 206 is the metal-containing film that is formed in processing method 100. In some embodiments, the metal-containing precursor comprises aluminum chloride (AlCl₃) and the reactant comprises ammonia (NH₃) to form a metal-containing film 206 comprising aluminum nitride (AlN). In some embodiments, the metal-containing film 206 has a thickness in a range of from 3 Å to 200 Å, including all subranges and values therebetween.

Further aspects of the disclosure pertain to a method that is part of a gap fill process. The inventive methods may be utilized with any device nodes, but may be particularly advantageous in device nodes of about 25 nm or less, for example about 5 nm to about 25 nm. In some embodiments, a metal-containing film is deposited, such as by the processing method 100, on a dielectric surface with one or more high aspect ratio gap features, including vertical gap features and/or horizontal gap features, and the molybdenum in the gap features forms horizontal interconnects through which current flows.

FIGS. 3A-3C depict cross-sectional views of a deposition process on a substrate 302 including at least one feature 300 that has a gap defined by a top surface 303, two opposed sidewalls 320 and a bottom surface 330. Referring first to FIG. 3A, a substrate 302 is shown having a single feature 300. Referring to FIG. 3B, in one or more embodiments, a conformally deposited metal-containing film 306 is shown directly on the top surface 303 and along the two opposed sidewalls 320 and the bottom surface 330. Referring to FIG. 3C, in one or more embodiments, the conformally deposited metal-containing film 306 is shown directly on the top surface 303 and along the two opposed sidewalls 320 and the bottom surface 330 and filling the at least one feature 300.

The Figures show a substrate 302 having a single feature 300 for illustrative purposes; however, those skilled in the art will understand that there can be more than one feature 300. The shape of the feature 300 can be any suitable shape including, but not limited to, trenches and cylindrical vias, as described herein.

In one or more embodiments, the at least one feature 300 comprises one or more of a trench or a via. In specific embodiments, the at least one feature 300 comprises a trench. In still further embodiments, the term “at least one feature 300” and “trench 300” may be used interchangeably. The trench 300 has a depth to the bottom surface 330 and a width between the two opposed sidewalls 320. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In some embodiments, the trench 300 has an aspect ratio (depth/width) in a range of 1:1 to 20:1, 1:1 to 15:1, 3:1 to 15:1, 5:1 to 20:1, 5:1 to 15:1, 10:1 to 20:1, 10:1 to 15:1, or 15:1 to 20:1.

It has advantageously been found that co-flowing the pulse of the metal-containing precursor and the pulse of the reactant, as in processing method 100, enables better delivery of the metal-containing precursor and reactant, as the metal-containing precursor and/or the reactant are charged during the mini purge, leading to improved conformality of the metal-containing film.

The substrate 302 can be any suitable substrate material including the non-limiting materials of substrate 202. In one or more embodiments, the substrate 302 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 302 comprises one or more of silicon (Si), germanium (Ge), gallium (Ga), arsenic (As), indium (In), phosphorus (P), or selenium (Se). Although a few examples of materials from which the substrate 302 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the substrate 302 may include dielectric materials, for example, silicon-containing dielectric materials and/or metal oxide dielectric materials. In some embodiments, the substrate 302 may comprise one or more dielectric surfaces comprising a low-K dielectric material such as, but not limited to, silicon oxide (SiOx), silicon sub-oxides, silicon nitride (SiNₓ), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof.

Referring to FIG. 3C, the method comprises conformally depositing a metal-containing film 306 on the top surface 303 and along the two opposed sidewalls 320 and the bottom surface to fill the feature 300, the conformally deposited metal-containing film 306 substantially free of seams or voids. As used in this regard, “substantially free” means that less than about 5%, including less than about 4%, less than about 3%, less than about 2%, less than about 1%, less than about 0.5%, and less than about 0.1% of the total composition of the conformally deposited metal-containing film 306, on an atomic basis, comprises voids and/or seams. The feature 300 may be exposed to, for example, one or more cycles of processing method 100 to a desired thickness to fill the feature 300.

In some embodiments, the metal-containing film 306 is laterally bounded by the two opposed sidewalls 320 of the at least one feature 300. As used in this regard, “laterally bounded” means that the deposited material does not extend beyond the point of intersection between the top surface 303 and the two opposed sidewalls 320. In some embodiments, the metal-containing film 306 extends above the at least one feature 300. In some embodiments, the metal-containing film 306 fills the trench 300. As used in this regard, a film which “fills the trench 300” has a volume which occupies at least 95%, at least 98%, or at least 99% of the volume of the trench 300. In some embodiments, the metal-containing film which fills the trench 300 has a fill height in a range of from 30 nm to 75 nm, including in a range of from 40 nm to 60 nm.

The methods described herein may be performed in any suitable processing chamber known to the skilled artisan. The methods described herein may be performed in, for example, an atomic layer deposition (ALD) processing chamber (including a spatial ALD processing chamber), a chemical vapor deposition (CVD) processing chamber, or a pulsed CVD (pCVD) processing chamber. Examples of a processing system that may be suitably modified in accordance with the teachings provided herein include the Endura®, Producer®, Centura®, Continuum®, Olympia®, Tesseract™, PRODUCER® systems and any related PRODUCER platforms, PRECISION 5000® systems, Trillium®, and/or a Selectra™ Etch chamber integrated processing systems or other suitable processing systems commercially available from Applied Materials, Inc., located in Santa Clara, California.

The methods described herein may be performed in any suitable processing system and/or processing chamber that can be controlled by the PLC (as described herein) having improved control over precursor/reactant pulse/purge time to less than or equal to 0.05 seconds. In some embodiments, the metal-containing precursor and/or the reactant are charged during the mini purge to avoid precursor/reactant depletion.

Embodiments of the disclosure are directed to processing tools. In some embodiments, the processing tool comprises: a central transfer station comprising a robot configured to move a wafer, a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises one or more of a chemical vapor deposition (CVD) chamber or an atomic layer deposition (ALD) chamber. In some embodiments, the controller is configured to activate the robot to move the wafer between process stations, and to control a processing method for forming a metal-containing film on the wafer, the processing method comprising exposing the wafer to a constant flow of an inert gas and a co-flow of a pulse of a metal-containing precursor and a pulse of a reactant to form the metal-containing film, the pulse of the metal-containing precursor and the pulse of the reactant interrupted by a mini purge, wherein the metal-containing precursor is charged during the mini purge.

In some embodiments, the controller is a programmable logic controller (PLC) with improved control over precursor/reactant pulse/purge time to less than or equal to 0.05 seconds. In some embodiments, the metal-containing precursor and/or the reactant are charged during the mini purge to avoid precursor/reactant depletion.

FIG. 4 illustrates a schematic top-view diagram of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 400. Accordingly, the processing system 400 may provide for an integrated solution for some processing of wafers.

Examples of a processing system that may be suitably modified in accordance with the teachings provided herein include the Endura®, Producer®, Centura®, Continuum®, Olympia®, Tesseract™, PRODUCER® systems and any related PRODUCER platforms, PRECISION 5000@ systems, Trillium®, and/or a Selectra™ Etch chamber integrated processing systems or other suitable processing systems commercially available from Applied Materials, Inc., located in Santa Clara, California.

It is contemplated that other processing systems (including those from other manufacturers) may be adapted to benefit from aspects described herein.

In the illustrated example of FIG. 4, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes. The processing chamber 422 may be a SiCoNi™ Preclean chamber available from Applied Materials of Santa Clara, Calif. The processing chamber 420 may be a Selectra™ Etch chamber available from Applied Materials of Santa Clara, Calif.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

In some embodiments, the operations of the methods described herein are each performed within the same processing chamber. In some embodiments, the operations of the methods described herein are each performed within a different processing chamber. In some embodiments, the different processing chambers are connected as part of a processing system. In some embodiments, the operations of the methods described herein are performed without an intervening vacuum break.

In some embodiments, one or more of the operations of the methods of this disclosure (e.g., processing method 100) is performed in situ, as described herein. In some embodiments, one or more of the operations of the methods of this disclosure (e.g., processing method 100) is performed ex situ, as described herein.

One or more embodiments of the disclosure are directed to a non-transitory computer readable medium including instructions, that, when executed by a controller of a processing chamber, cause the processing chamber to perform the methods (e.g., the processing method 100) described herein. In some embodiments, the non-transitory computer readable medium includes instructions, that, when executed by a controller of a processing chamber, cause the processing chamber to: repeat processing method 100 in range of 1 to 10 times and/or until a desired thickness of the metal-containing film is reached.

In some embodiments, the non-transitory computer readable medium includes instructions, that, when executed by a controller of a processing chamber, cause the processing chamber to: conformally deposit a metal-containing film on a top surface and along two opposed sidewalls and a bottom surface of a feature by exposing the feature to one or more process cycles of processing method 100. In some embodiments, the non-transitory computer readable medium includes instructions, that, when executed by a controller of a processing chamber, cause the processing chamber: to conformally deposit the metal-containing film on the top surface and along the two opposed sidewalls and the bottom surface of the feature by exposing the feature to one or more process cycles of processing method 100 to a desired thickness to fill the feature.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1

A metal-containing film was formed on a substrate by processing method 100, comprising exposing a substrate to a constant flow of an inert gas and a co-flow of a pulse of a metal-containing precursor and a pulse of a reactant. The pulse of the metal-containing precursor was about 50 milliseconds. The pulse of the reactant was about 50 milliseconds. The pulse of the metal-containing precursor and the pulse of the reactant were interrupted by a mini purge lasting about 500 milliseconds.

Four process cycles were completed. Each process cycle was performed at a temperature of 450° C. The thickness of the metal-containing film formed was measured after each process cycle. At the second process cycle, for example, the metal-containing film has a thickness of about 10 Å. At the fourth process cycle, for example, the metal-containing film has a thickness of greater than 20 Å.

### Comparative Example 2

A metal-containing film was formed by a traditional atomic layer deposition process by sequentially exposing a substrate to a metal-containing precursor, purge, a reactant, and purge.

Twenty process cycles were completed. Each process cycle was performed at a temperature of 450° C. The thickness of the metal-containing film formed was measured after each process cycle. At the eighth process cycle, for example, the metal-containing film has a thickness of about 5 Å. At the twentieth process cycle, for example, the metal-containing film has a thickness of less than 20 Å.

Accordingly, forming a metal-containing film by processing method 100 (Example 1) shows substantially greater growth per cycle (GPC) and greater than 300% throughput improvement compared to traditional ALD processes, described in Comparative Example 2.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least the embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing method comprising:
exposing a substrate to a constant flow of an inert gas and a co-flow of a pulse of a metal-containing precursor and a pulse of a reactant to form a metal-containing film on the substrate, the pulse of the metal-containing precursor and the pulse of the reactant interrupted by a mini purge, wherein the metal-containing precursor is charged during the mini purge.

2. The processing method of claim 1, wherein the pulse of the metal-containing precursor is longer than the pulse of the reactant.

3. The processing method of claim 2, wherein the pulse of the metal-containing precursor is in a range of from greater than or equal to 50 milliseconds to less than or equal to 500 milliseconds and the pulse of the reactant is in a range of from greater than or equal to 500 milliseconds to less than or equal to 1 second.

4. The processing method of claim 1, wherein the pulse of the reactant is longer than the pulse of the metal-containing precursor.

5. The processing method of claim 4, wherein the pulse of the reactant is in a range of from greater than or equal to 50 milliseconds to less than or equal to 500 milliseconds and the pulse of the metal-containing precursor is in a range of from greater than or equal to 500 milliseconds to less than or equal to 1 second.

6. The processing method of claim 1, wherein the pulse of the metal-containing precursor is in a range of from greater than or equal to 50 milliseconds to less than or equal to 500 milliseconds and the pulse of the reactant is in a range of from greater than or equal to 50 milliseconds to less than or equal to 500 milliseconds.

7. The processing method of claim 1, wherein the mini purge is in a range of from greater than or equal to 50 milliseconds to less than or equal to 1000 milliseconds.

8. The processing method of claim 1, wherein the metal-containing precursor comprises one or more of aluminum chloride (AlCl₃), hafnium tetrachloride (HfCl₄), niobium chloride (NbCl₅), molybdenum pentachloride (MoCl₅), tungsten pentachloride (WCl₅), tungsten hexachloride (WCl₆), tungsten (V) chloride (W₂Cl₁₀), molybdenum dioxide dichloride (MoO₂Cl₂), tungsten oxytetrachloride (WOCl₄), antimony trichloride (SbCl₃), tellurium tetrachloride (TeCl₄), tantalum pentachloride (TaCl₅), Tris(N,N′-di-i-propylformamidinato)lanthanum (III), Tetrakis(dimethylamino)titanium (TDMAT), Pentakis(dimethylamino) tantalum (PDMAT).

9. The processing method of claim 1, wherein the reactant comprises ammonia (NH₃).

10. The processing method of claim 1, wherein the inert gas comprises one or more of nitrogen (N₂), argon (Ar), or helium (He).

11. The processing method of claim 1, performed at a temperature in a range of 200° C. to 500° C.

12. The processing method of claim 1, performed at a pressure in a range of from 2 Torr to 300 Torr.

13. The processing method of claim 1, wherein the metal-containing film has a thickness in a range of from 3 Å to 200 Å.

14. The processing method of claim 1, further comprising charging the reactant during the mini purge.

15. The processing method of claim 1, comprising repeating the method in a range of 1 to 10 times.

16. A processing method comprising:
exposing a substrate including at least one feature to a process cycle, the at least one feature comprising a surface defining a trench, the trench comprising a top surface, a bottom surface, and two opposed sidewalls comprising a dielectric material, the process cycle comprising exposing the top surface, the bottom surface, and the two opposed sidewalls to a constant flow of an inert gas and a co-flow of a pulse of a metal-containing precursor and a pulse of a reactant to conformally deposit a metal-containing film on the at least one feature, the pulse of the metal-containing precursor and the pulse of the reactant interrupted by a mini purge, wherein the metal-containing precursor is charged during the mini purge.

17. The processing method of claim 16, wherein the metal-containing precursor comprises aluminum chloride (AlCl₃) and the reactant comprises ammonia (NH₃).

18. The processing method of claim 16, wherein the dielectric material comprises silicon oxide (SiOₓ), silicon nitride (SiNₓ), silicon carbide (SiCx), silicon carbonitride (SiCxNy), silicon oxynitride (SiOxNy), a low-K dielectric material, or combinations thereof.

19. The processing method of claim 16, wherein the at least one feature has an aspect ratio in a range of from 1:1 to 20:1.

20. A processing tool comprising:
a central transfer station comprising a robot configured to move a wafer;
a plurality of process stations, each process station connected to the central transfer station and providing a processing region separated from processing regions of adjacent process stations, the plurality of process stations comprising one or more of a chemical vapor deposition (CVD) chamber or an atomic layer deposition (ALD) chamber; and
a controller connected to the central transfer station and the plurality of process stations, the controller configured to activate the robot to move the wafer between process stations, and to control a processing method for forming a metal-containing film on the wafer, the processing method comprising exposing the wafer to a constant flow of an inert gas and a co-flow of a pulse of a metal-containing precursor and a pulse of a reactant to form the metal-containing film, the pulse of the metal-containing precursor and the pulse of the reactant interrupted by a mini purge, wherein the metal-containing precursor is charged during the mini purge.
